(19) United States
(12) Patent Application Publication
(10) Pub. No.: US 2006/0001116 A1
(43) Pub. Date: Jan. 5, 2006

(54) Semiconductor module with a semiconductor sensor chip and a plastic package as well as method for its production

(76) Inventors: Albert Auburger, Regenstauf (DE); Stefan Paulus, Zeitlarn (DE); Adolf Koller, Regensburg (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 11/143,206

(22) Filed: Jun. 2, 2005

(30) Foreign Application Priority Data
Jun. 2, 2004 (DE) 10 2004 027 094.5

(51) Int. Cl. H01L 31/0203

(52) U.S. Cl. 257/433

(57) ABSTRACT

The invention relates to a semiconductor module with a semiconductor sensor chip and an associated method. The sensor chip has a sensor region, and nonsensitive regions of the sensor chip are embedded in a nontransparent plastic package molding compound. The sensor region of the sensor chip is operably coupled to the external surroundings of the module via an opening in the nontransparent plastic package molding compound. The opening in the molding compound is formed by laser ablation.

### REFERENCE TO RELATED APPLICATIONS

This application claims the benefit of the priority date of German application DE 10 2004 027 094.5, filed on Jun. 2, 2004, the contents of which are herein incorporated by reference in their entirety.

### FIELD OF THE INVENTION

The invention relates to a semiconductor module with a semiconductor sensor chip and a plastic package as well as to a method for its production. The sensor chip of this semiconductor module has a sensor region and is electrically in connection with at least one further component of the semiconductor module, with at least the further component embedded in a plastic molding compound.

### BACKGROUND OF THE INVENTION

Semiconductor modules are known, for example, as disclosed in German patent application DE 103 30 739.7. In this known embodiment of a semiconductor module, although a semiconductor chip is embedded in a nontransparent plastic package molding compound, the entire sensor chip with its electrical connections is freely accessible and consequently exposed to the surroundings. A semiconductor module of this type has the disadvantage that the sensitive electrical connections do not withstand excessive loading, in particular not under high alternating thermal loading, as required in automotive engineering. Problems concerning the reliability of such semiconductor modules with a freely accessible sensor chip arise in such circumstances.

In order to overcome these problems, a solution such as that depicted in prior art FIG. 12 has been proposed. FIG. 12 shows a semiconductor module 30 of the prior art in which the sensor chip 1 is completely embedded in a plastic molding compound of transparent material 13 together with a further component 4. This plastic molding compound is surrounded by a package 2 of a nontransparent plastic molding compound 8. The components 16 of this semiconductor module 30 are arranged on chip islands 17 of inner flat conductors 18, with bonding wire connections establishing electrical connections 6 between contact areas 21 of the active upper sides 22 of the components and external contacts 24 in the form of outer flat conductors 26 via the inner flat conductors 18. For this purpose, the inner flat conductors 18 have contact terminal areas 23 for the bonding wire connections.

In the case of the semiconductor device with an optical sensor chip 1, although the sensor chip and further components of the semiconductor module are protected by the transparent material, the form of construction is so complex that, in extreme temperature cycles such as are used in automotive engineering tests, the enclosing transparent material 13 presents problems in interaction with the molded nontransparent plastic package molding compound 8, so that reliable optical coupling via the opening 9 in the nontransparent plastic package molding compound 8 is not ensured.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present one or more concepts of the invention in a simplified form as a prelude to the more detailed description that is presented later.

The invention is directed to a semiconductor module with a semiconductor sensor chip and a package that reduces the problems mentioned above in the prior art and permits reliable access to the sensor.

According to the invention, a semiconductor module and a method for its production are provided, the semiconductor module having a semiconductor sensor chip and a package. The sensor chip has a sensor region in the package, and is electrically in connection with at least one further component of the semiconductor module. These electrical connections, the further component and the nonsensitive regions of the sensor chip are embedded in a nontransparent plastic package molding compound. However, the sensor region of the sensor chip is in operative connection with the surroundings via an opening in the nontransparent plastic package molding compound, the opening having a laser-ablated well.

An advantage of the semiconductor module according to the invention is that no special molding tools are required for molding cavities or for molding cavity packages. Furthermore, since the opening of a laser-ablated well is only created at a subsequent time, the occurrence of mold flash in the cavities to be created for semiconductor sensor devices is avoided. Furthermore, it is an advantage of at least one embodiment of the invention that the laser-ablated well can be provided to the desired depth or to the active chip surface, the sensor region, without damaging the sensor region. For this purpose, use is made of the material-related differences between the absorbing nontransparent plastic materials and the laser-reflecting surface of a semiconductor sensor region.

The exposing of the opening by means of a laser technique is consequently unproblematical. A further advantage of the semiconductor module lies in the use of the black, fully encapsulating molding composite. The reliability of this packaging technology is proven and satisfies the new requirements for optical and mechanical sensors, in particular in automotive engineering.

Furthermore, in one embodiment the reliability of the sensor module is further improved by the use of only a single material for the enclosure of the device components. Finally, the enclosure of the nonsensitive regions of the sensor chip with the nontransparent plastic package molding compound means that these regions of the sensor chip are particularly protected and fixed in the semiconductor module in such a way that the semiconductor module according to the invention can withstand undamaged extreme temperature fluctuations such as those that occur in automotive engineering. Semiconductor modules with a package of this type and a laser-ablated well which limits the influence of the surroundings on the sensor region of the sensor chip have proven to be very successful even under extreme thermal cycles.

To protect the surface of the sensor region from aggressive surroundings, the laser-ablated well may be partly filled with a transparent material. The thickness of this transparent material is dimensioned such that the optical properties of a receiver diode or a transmitter diode are not impaired. For micromechanical and pressure-sensitive semiconductor modules, the laser-ablated well may be filled with an elastomeric and transparent material. The elastomeric material is used for pressure-sensitive sensors, since it advantageously does not falsify the pressure measurement.

In a further embodiment of the invention, the components of the semiconductor module are fixed with a material bond on chip islands of inner flat conductors. This fixing with a material bond on metallic flat conductors has proven to be particularly successful in automotive engineering, especially since heat can be dissipated to the outside via these inner flat conductors. For semiconductor modules that are subjected to less thermal loading, it is also possible to fix the semiconductor chips with a material bond on chip islands of a wiring substrate of a BGA (ball grid array) or LGA (land grid array) package. This wiring and connection technology has not yet become established in automotive engineering however, especially since the heat dissipation via a wiring substrate is more problematical than via metallic flat conductors.

The aforementioned electrical connections are preferably configured as bonding wire connections. These bonding wire connections connect electrical contact areas of the active upper sides of the components to contact terminal areas on the inner flat conductors if the semiconductor module is based on a flat conductor technique or to contact terminal areas on the wiring substrate if the semiconductor module is fitted in a BGA or LGA package. Since the bonding wire connections of the sensor chip in one embodiment are completely embedded in the nontransparent plastic package molding compound, and are also not exposed by the laser-ablated well, a semiconductor module which has a high strength with respect to mechanical loads and with respect to thermomechanical stresses is obtained.

If the flat conductor technique is used for the semiconductor module, the inner flat conductors go over into outer flat conductors which protrude laterally from the plastic package molding compound as external contacts. If a wiring substrate is used for the semiconductor module, the components including the sensor chip are arranged on the upper side of the wiring substrate, and the external contacts are attached on the underside of the wiring substrate in the form of solder balls. The aforementioned connections with a material bond between the semiconductor chip and the chip islands of the flat conductor technique preferably have a eutectic soldered connection. Soldered connections of this type have the advantage over adhesively bonded connections of a higher temperature resistance, which is decisive in particular in automotive engineering.

In order to allow even better results to be achieved, the connections with a material bond have diffusion brazed connections. In the case of such diffusion brazed connections, intermetallic phases occur, with a melting point that is higher than the temperature during the diffusion brazing operation. Solder paste connections also form metallic connecting components once the volatile constituents of the solder paste have escaped during the process of sintering together to form a connection with a material bond.

As already mentioned, the semiconductor module according to one embodiment of the invention can be advantageously used as an optical sensor and/or optical receiver in automotive engineering, and in particular by means of fiber-optic cable harnesses. It has been found in this case that the highly complex solutions such as those shown in prior art FIG. 12 do not withstand the high temperature fluctuations that are expected in automotive applications. By contrast, however, the simple form of construction according to the invention has proven successful for semiconductor modules with a semiconductor sensor chip. Apart from the optical application as a transmitter and/or receiver, a sensor chip of this type may also be formed as a pressure-sensitive or temperature-sensitive sensor and has a preferred use in automotive engineering, although it may be employed in other applications.

A method for producing a semiconductor module with a semiconductor sensor chip and a package according to one embodiment of the invention has the following method steps. Firstly, a leadframe with semiconductor chip positions and contact terminal areas for electrical connections to external contacts is produced for at least one semiconductor module. After producing a leadframe, a semiconductor sensor chip with a sensor region and at least one further component is applied to the leadframe by connecting the components to the leadframe with a material bond. Subsequently, electrical connections are established between contact terminal areas of the leadframe and contact areas of the components. Subsequently, a nontransparent plastic package molding compound is applied, embedding the components and electrical connections and enclosing the leadframe, the components and the electrical connections. As the final step, the sensor region of the semiconductor sensor chip is then exposed by means of a laser ablation technique while forming a laser-ablated well.

A method of this type has the advantage that no special molding tools have to be prepared for the access to the sensor region of the sensor chip. Rather, after complete enclosure of the sensor chip, the sensor region is exposed with the aid of the laser ablation technique, the different ablation rate between the nontransparent plastic and the highly reflective semiconductor surface being used to expose the sensor region of the semiconductor sensor chip without damage. In this method it is possible to expose not only optical sensor regions but also sensor regions for mechanical parameters such as pressure and force, as well as fluid-sensitive regions which permit gas analyses and liquid analyses and temperature-sensitive regions of semiconductor chips.

In the case of one example of how the method is carried out, a laser device and a mirror drum of a polygonal cross section are used for the laser ablation. In this case, the mirror drum rotates about a horizontal longitudinal axis, while the laser device or a plane mirror in the laser beam is pivoted about a vertical axis in order to deflect the laser beam along the longitudinal extent of the mirror drum. Instead of the mirror drum, a plane mirror which can be pivoted about a horizontal axis may also be used. This two-dimensional deflection of the laser beam achieves a sweep or ablation over a surface area, so that an opening can be produced over the sensor region. Other forms of construction for such laser ablation techniques are possible, but the mirror deflection is used preferably in one example to produce a laser-ablated well over the sensitive sensor region of the semiconductor sensor chip.

The leadframe is suitable for producing a number of semiconductors in corresponding semiconductor module positions of the leadframe. For this purpose, a leadframe of this type has semiconductor module positions arranged in rows and columns. If the semiconductor module is based on a wiring substrate, a panel can be used for a number of semiconductor modules. On the other hand, in the case of a flat conductor technique, the leadframe is a flat conductor frame from which the individual semiconductor modules are punched out after completion of the laser-ablated opening. Both the panel and the flat conductor frame have the advantage that the production steps can largely take place concurrently generally in parallel for a number of semiconductor modules.

In summary, according to the invention an access to the sensor region of a semiconductor sensor chip can be advantageously created by the production of an opening in a completely encapsulated package, while all the other components of the semiconductor module remain under the protection of a nontransparent plastic package molding compound. The essence of the invention consequently comprises improving the process by cutting out an opening in an already completely encapsulated package. In this case, all the nonsensitive regions of the sensor chip and all the nonsensitive components of the semiconductor module are protected from mechanical damage and thermomechanical stresses.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

The invention is now explained in more detail on the basis of the accompanying figures.

FIG. 1 is a schematic cross section illustrating a semiconductor module according to a first embodiment of the invention;

FIGS. 2 to 7 are schematic cross sections illustrating components in the course of the production of a semiconductor module according to FIG. 1, and more particularly,

FIG. 2 is a schematic cross section illustrating a semiconductor module position of a flat conductor frame;

FIG. 3 is a schematic cross section illustrating the semiconductor module position according to FIG. 1 after applying semiconductor chips or after applying components;

FIG. 4 is a schematic cross section illustrating a semiconductor module position according to FIG. 3 after applying bonding wire connections;

FIG. 5 is a schematic cross section illustrating the semiconductor module position according to FIG. 4 after applying a nontransparent plastic package molding compound;

FIG. 6 is a schematic cross section illustrating the semiconductor module position according to FIG. 5 during a laser ablation;

FIG. 7 is a schematic cross section illustrating the semiconductor module position according to FIG. 6 after exposing the sensor region of the semiconductor sensor chip;

FIG. 8 is a schematic cross section illustrating a semiconductor module according to a second embodiment of the invention;

FIG. 9 is a schematic cross section illustrating a semiconductor module according to a third embodiment of the invention;

FIG. 10 is a schematic cross section illustrating a semiconductor module according to a fourth embodiment of the invention;

FIG. 11 is a schematic cross section illustrating a semiconductor module according to a fifth embodiment of the invention;

FIG. 12 is a schematic cross section illustrating a semiconductor module according to the prior art.

### DETAILED DESCRIPTION OF THE INVENTION

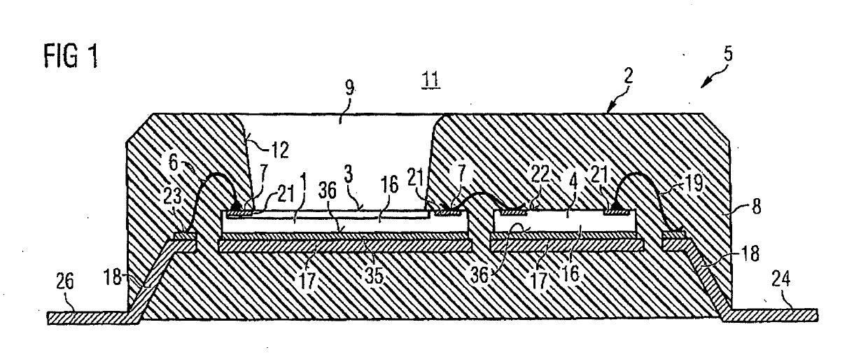

FIG. 1 shows a schematic cross section through a semiconductor module 5 according to a first embodiment of the invention. This semiconductor module 5 has a sensor chip 1 and a further component 4 in the form of a semiconductor chip, which are positioned on chip islands 17 of inner flat conductors 18. The components 16 are fixed by their back sides 36 with a material bond by a layer of solder 35 on the chip islands 17. Electrical connections 6 in the form of bonding wire connections 19 connect contact areas 21 of the active upper side 22 of the components 16 to contact terminal areas 23 on inner flat conductors 18.

The inner flat conductors 18 go over outwardly into outer flat conductors 24 and form external contacts 26. The components 16 of the semiconductor module 5, such as the semiconductor chips, the bonding wire connections 19, the inner flat conductors 18 and the chip islands 17, are embedded in a nontransparent plastic molding compound 8. Of the sensor chip 1, the nonsensitive regions 7 are likewise surrounded by the plastic package molding compound 8, while the sensor region 3 is freely accessible for the surroundings 11 through an opening 9. For this purpose, the package 2 of this first embodiment of the invention has a laser-ablated well 12, which merely allows access to the sensor region 3 of the semiconductor sensor chip 1. Consequently, the sensitive bonding wire connections 19 in particular are protected from mechanical damage and from thermomechanical stresses.

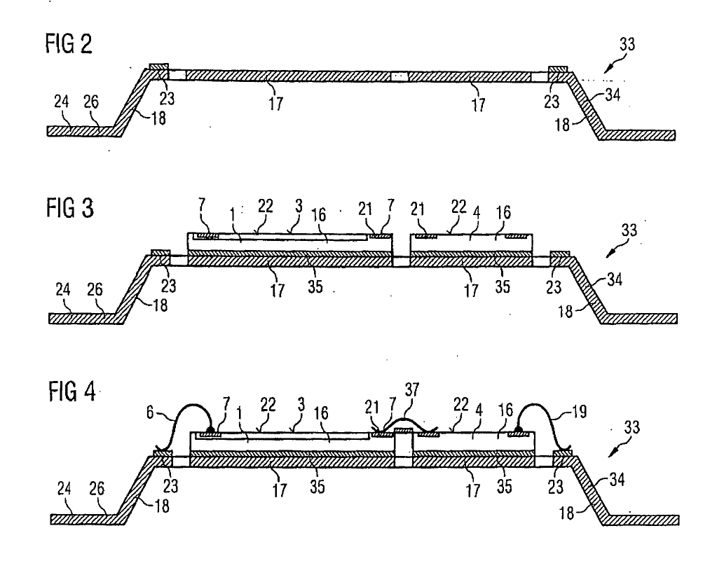

FIGS. 2 to 7 show schematic cross sections of components in the course of the production of a semiconductor module 5 according to FIG. 1. Components with the same functions as in FIG. 1 are identified by the same reference numerals in FIGS. 2 to 7 and are not separately discussed.

FIG. 2 shows a schematic cross section of a semiconductor module position 33 of a flat conductor frame 34. The semiconductor module position 33 has two chip islands 17, which are electrically connected to the inner flat conductors 18, the inner flat conductors 18 being cranked or angled away and going over into outer flat conductors 24 of the flat conductor frame 34. The outer flat conductors 24 at the same time form external contacts 26 for the semiconductor module.

FIG. 3 shows a schematic cross section of the semiconductor module position 33 according to FIG. 1 after applying semiconductor chips. For this purpose, the sensor chip 1 with a sensor region 3 is applied to one of the chip islands 17, the sensor chip 1 having contact areas 21 in its nonsensitive edge regions 7. The sensor chip 1 is fixed on the chip island 17 by a eutectic soldered connection, so that it is positioned for the subsequent establishment of bonding wire connections between the contact areas 21 of the sensor chip 1 and contact terminal areas 23 of the inner flat conductors 18.

The contact terminal areas 23 may have a finish coating to facilitate the bonding. In this case, the combination of aluminum and gold is of advantage, because the gold-aluminum two-phase system forms a low-melting eutectic and consequently facilitates the thermosonic bonding. After the fixing of the semiconductor chips on the flat conductor frame 34 in the semiconductor module position 33, bonding can then follow.

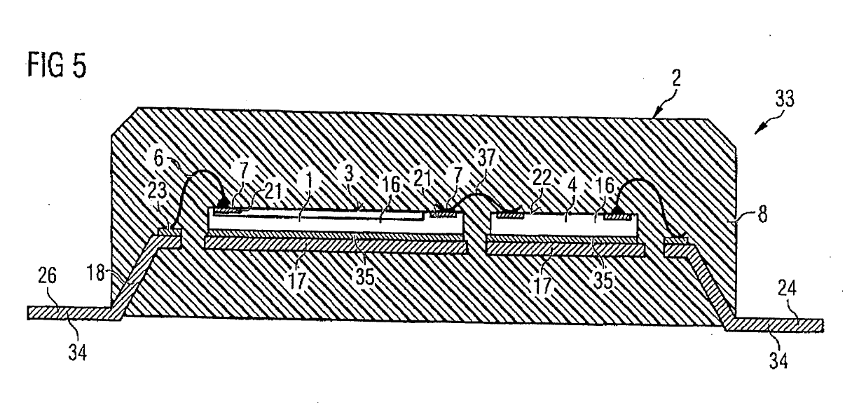

FIG. 4 shows a schematic cross section of the semiconductor module position 33 according to FIG. 3 after providing bonding wire connections 19. The bonding wire connections 19 connect not only the semiconductor chips to the inner flat conductors 18 of the flat conductor frame 34, but can also extend from semiconductor chip to semiconductor chip, as the bonding connection 37 shows.

FIG. 5 shows a schematic cross section of the semiconductor module position 33 according to FIG. 4 after applying a nontransparent plastic package molding compound 8. This plastic package molding compound 8 embeds all the components such as the components, the bonding wire connections 19 and 37 as well as the inner flat conductors 18. The sensor region 3 of the sensor chip 1 is no longer accessible after this method step.

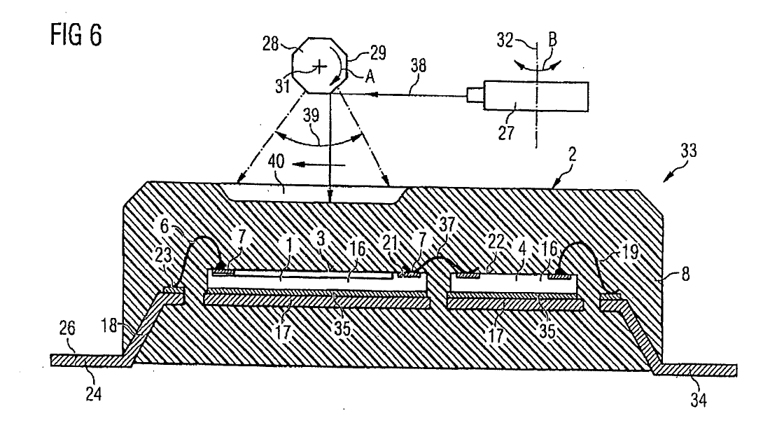

FIG. 6 shows a schematic cross section of the semiconductor module position 33 according to FIG. 5 during laser ablation. The laser device 27 is arranged in such a way that it horizontally emits a laser beam 38, which falls on a mirror drum 28 rotating in the direction of the arrow A. The polygonal cross section 29 of the mirror drum 28 has the effect that, when the mirror drum 28 rotates about a horizontal longitudinal axis 31, the laser beam 38 is deflected in a limited laser beam region 39, so that a cavity 40 forms in the nontransparent plastic molding compound 8. This cavity 40 extends two-dimensionally, which can be achieved by either the laser device 27 being pivoted back and forth about a vertical axis 32 in the direction of the arrow B or a further pivotable plane mirror (not shown) in the laser beam 38 being pivoted back and forth about the vertical axis 32, so that the mirror surfaces of the mirror drum 28 are irradiated parallel to the horizontal longitudinal axis 31 of the mirror drum 28. This causes the laser beam 38 to extend over a surface area, whereby an opening can be dug into the plastic package molding compound 8.

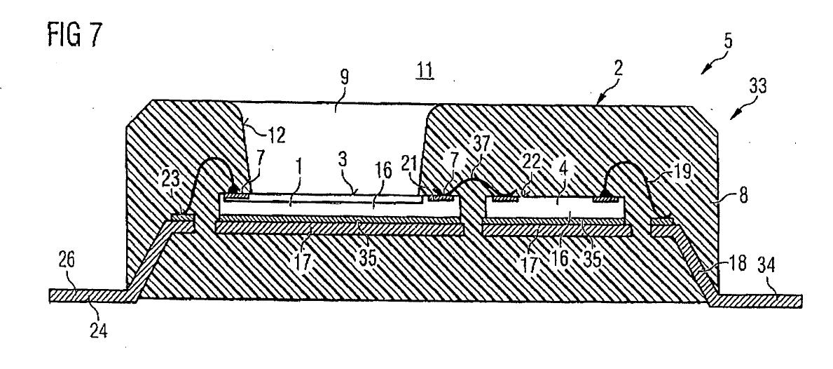

FIG. 7 shows a schematic cross section of the semiconductor module position 33 according to FIG. 6 after exposing the sensor region 3 of the semiconductor sensor chip 1. In the laser ablation, which is shown in FIG. 6, an opening 9 in the form of a laser-ablated well 12 forms in the plastic package molding compound 8 over the sensor region 3. This laser-ablated well 12 has the advantage that it can be introduced very precisely into the plastic package molding compound 8, and that the nonsensitive regions 7 of the sensor chip remain protected by the plastic package molding compound 8.

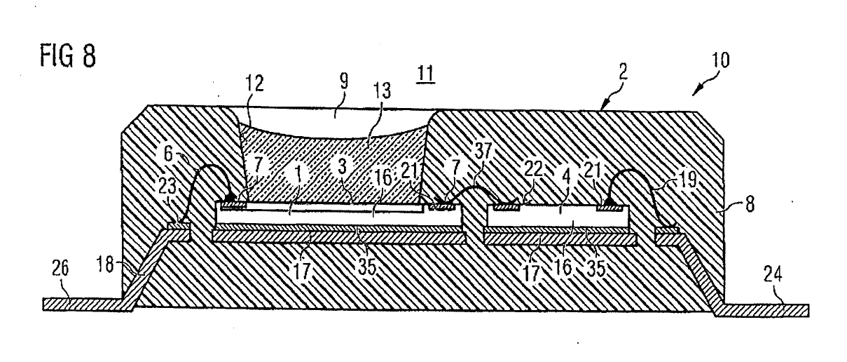

FIG. 8 shows a schematic cross section through a semiconductor module 10 according to a second embodiment of the invention. Components with the same functions as in the previous figures are identified by the same reference numerals and are not separately discussed. The second embodiment of the invention differs from the first embodiment of the invention according to FIG. 1 in that the sensor region 3 is protected by the opening 9 being partly filled with an optically transparent material 13.

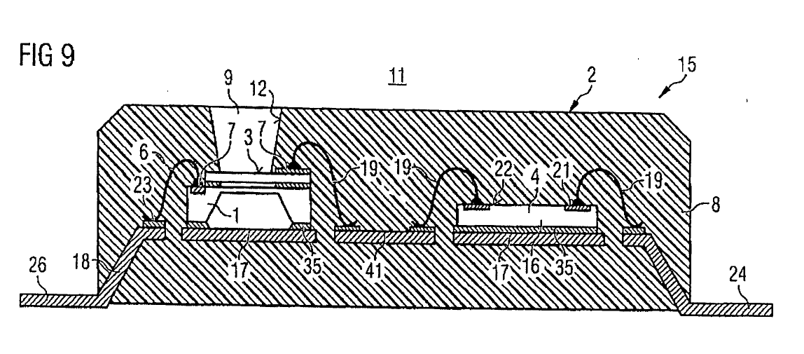

FIG. 9 shows a schematic cross section through a semiconductor module 15 according to a third embodiment of the invention. Components with the same functions as in the previous figures are identified by the same reference numerals and are not separately discussed. The third embodiment of the invention differs from the first two embodiments in that it provides a pressure sensor which has a micromechanical sensor for picking up acceleration forces and/or pressure forces. For this purpose, the sensor chip 1 has a special bridge form and is covered by a sensor platelet.

Furthermore, in the case of this embodiment of the invention, the flat conductor construction has a supporting conductor 41 between the sensor chip 1 and a further semiconductor chip, so that the mechanically sensitive bonding wire connections 19 between the two semiconductor chips can be shortened. It is also the case in this embodiment of the invention that firstly all the components were embedded in the plastic package molding compound 8, finally leaving exposed only the region of the micromechanical structure of the sensor chip, which is intended to remain free for a sensitive measurement of mechanical vibrations in the surroundings 11.

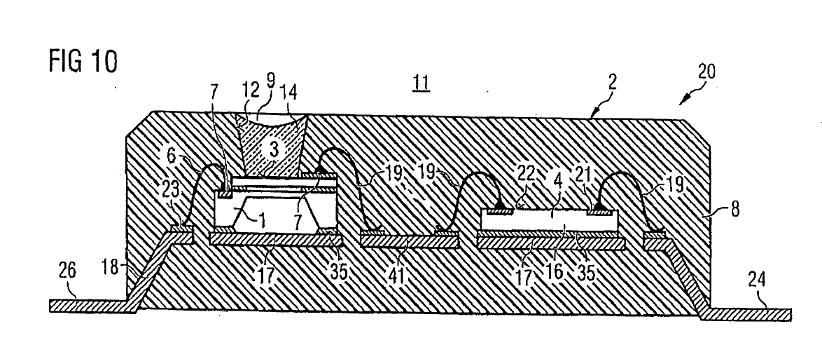

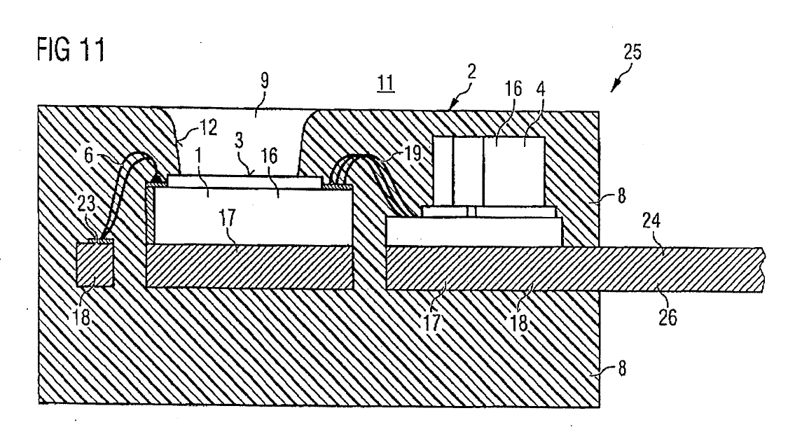

FIG. 10 shows a schematic cross section through a semiconductor module 20 according to a fourth embodiment of the invention. The fourth embodiment of the invention differs from the third embodiment in that the opening 9 over the sensor region 3 of the pressure-sensitive sensor chip 1 is partly filled with an elastomeric material 14, in order to protect the sensor opening 9 from penetration of liquids and gases such as occur in the engine compartment of a motor vehicle.

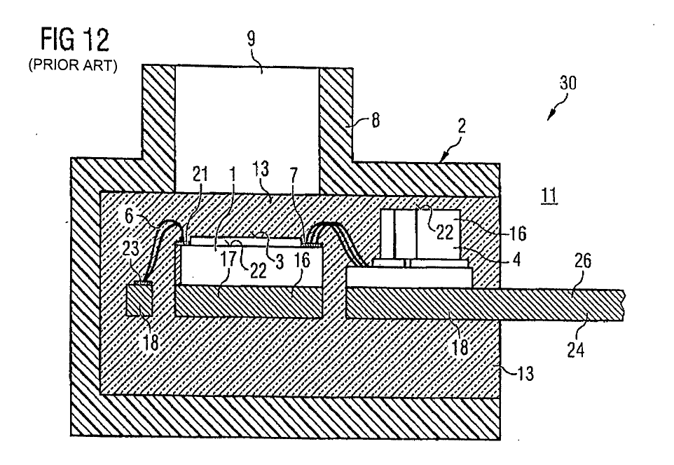

FIG. 11 shows a schematic cross section through a semiconductor module 25 according to a fifth embodiment of the invention. This fifth embodiment of the invention has the same components as the embodiment according to FIG. 12 corresponding to the prior art, but these components are covered by the nontransparent plastic package molding compound 8 apart from the sensitive region of the sensor chip 1. By introducing an opening 9 in the form of a laser-ablated well 12 over the sensitive region 7 of the sensor chip 1, the other nonsensitive areas and components 16 of the semiconductor module 25 remain protected by the plastic package molding compound 8 from mechanical damage and thermomechanical stresses.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. A semiconductor module, comprising:
a semiconductor sensor chip comprising a sensor region and one or more nonsensitive regions;
at least one further component connected to the sensor chip via electrical connections; and
a nontransparent plastic package molding compound surrounding the nonsensitive regions of the sensor chip, the at least one further component, and the electrical connections,
wherein the sensor region of the sensor chip is operably coupled to external surroundings of the semiconductor module via an opening in the nontransparent plastic package molding compound, wherein the opening comprises a laser-ablated well.

2. The semiconductor module of claim 1, further comprising a transparent material at least partly filling the laser-ablated well.

3. The semiconductor module of claim 1, further comprising an elastomeric material at least partly filling the laser-ablated well.

4. The semiconductor module of claim 1, further comprising chip islands comprising inner flat conductors, wherein the sensor chip and the at least one further component are fixed on respective ones of the chip islands with a material bond.

5. The semiconductor module of claim 4, wherein the chip islands are associated with a wiring substrate of a ball grid array or land grid array package.

6. The semiconductor module of claim 1, wherein the sensor chip and the at least one further component comprise active upper sides associated therewith, and further comprising a wiring substrate comprising inner flat conductors having contact terminal areas associated therewith, and wherein the electrical connections comprise bonding wire connections that connect contact areas of the active upper sides to contact terminal areas on the inner flat conductors of the wiring substrate.

7. The semiconductor module of claim 6, wherein the inner flat conductors protrude from the nontransparent plastic package molding compound to form outer flat conductors.

8. The semiconductor module of claim 6, wherein the wiring substrate has the sensor chip and the at least one further component on an upper side thereof, and solder balls on an underside thereof, thereby forming external contacts.

9. The semiconductor module of claim 4, wherein the material bond comprises a eutectic soldered connection.

10. The semiconductor module of claim 4, wherein the material bond comprises a diffusion brazed connection.

11. The semiconductor module of claim 4, wherein the material bond comprises a solder paste connection.

12. The semiconductor module of claim 1, wherein the sensor chip comprises an optical sensor.

13. The semiconductor module of claim 1, wherein the sensor chip comprises a pressure sensor or a temperature sensor.

14. A method for producing a semiconductor module with a semiconductor sensor chip having a sensor region associated therewith and at least one further component, comprising:
producing a leadframe comprising semiconductor module positions and contact terminal areas for electrical connections to external contacts associated therewith for the sensor chip and the at least one further component;
applying the semiconductor sensor chip with the sensor region and the at least one further component to the semiconductor module positions of the leadframe by connecting the components thereto with a material bond;
establishing electrical connections between contact areas of the sensor chip and the at least one further component, and between respective contact terminal areas of the leadframe and contact areas of the sensor chip and the at least one further component;
applying a nontransparent plastic package molding compound to the leadframe, thereby embedding the sensor chip and the at least one further component and the electrical connections associated therewith in the plastic package molding compound; and
exposing the sensor region of the semiconductor sensor chip by forming a well in the nontransparent plastic molding compound down to the sensor chip by means of laser ablation.

15. The method of claim 14, wherein exposing the sensor region by laser ablation comprises:
providing a laser device and a mirror drum having a polygonal cross section;
rotating the mirror drum about a horizontal longitudinal axis;
directing laser light from the laser device to the rotating mirror drum while the laser device or a plane mirror in the path of the laser beam is pivoted about a vertical axis in order to deflect the laser beam along a longitudinal extent of the mirror drum, thereby directing the laser beam toward a surface area of the nontransparent plastic package molding compound; and
removing the nontransparent plastic package molding compound using the laser beam to produce an opening over the sensor region by means of a sweep over a surface area.

16. A method of forming a semiconductor module, comprising:
providing a leadframe having two chip islands and a plurality of conductors;
attaching a semiconductor sensor chip having a sensor region and a nonsensitive region associated therewith and a further component to the chip islands, respectively;
providing electrical connections between the semiconductor sensor chip and the further component, and selectively between the plurality of conductors and the semiconductor sensor chip and further component, respectively;
covering the leadframe, the semiconductor sensor chip, and the further component with a nontransparent molding compound; and
forming an opening in the molding compound by laser ablation, thereby exposing solely the sensor region of the sensor chip.

17. The method of claim 16, wherein forming the opening comprises directing a laser beam over a surface area of the nontransparent molding compound that corresponds to the sensor region of the sensor chip, wherein the laser beam removes the nontransparent molding compound associated with the surface area.

18. The method of claim 17, wherein directing the laser beam further comprises:
directing the laser beam using a laser device to a mirror drum extending along a horizontal longitudinal axis having a polygonal cross section;
rotating the mirror drum about the horizontal longitudinal axis, thereby causing the laser beam to reflect off of the mirror drum toward the nontransparent molding compound and translating in a first direction;
pivoting the laser device about a vertical axis, thereby deflecting the laser beam along a longitudinal extent of the mirror drum, thereby causing the laser beam to reflect off of the mirror drum toward the nontransparent molding compound and translating in a second direction that is generally transverse to the first direction.

19. The method of claim 17, wherein directing the laser beam further comprises:
directing the laser beam using a laser device to a mirror drum extending along a horizontal longitudinal axis having a polygonal cross section;
rotating the mirror drum about the horizontal longitudinal axis, thereby causing the laser beam to reflect off of the mirror drum toward the nontransparent molding compound and translating in a first direction;
pivoting a plane mirror in the plane of the laser beam about a vertical axis, thereby deflecting the laser beam along a longitudinal extent of the mirror drum, thereby causing the laser beam to reflect off of the mirror drum toward the nontransparent molding compound and translating in a second direction that is generally transverse to the first direction.

20. The method of claim 16, further comprising filling at least a portion of the opening with a transparent material if the sensor chip is an optical sensor chip, or with an elastomeric material if the sensor chip is a pressure sensor chip.
